(19) United States
(12) Patent Application Publication
(10) Pub. No.: US 2025/0123334 A1
(43) Pub. Date: Apr. 17, 2025

(54) Battery Diagnosis Apparatus and Method

(71) Applicant: LG Energy Solution, Ltd., Seoul (KR)

(72) Inventors: Yong Chul Sung, Daejeon (KR); Cheol Taek Kim, Daejeon (KR)

(73) Assignee: LG Energy Solution, Ltd., Seoul (KR)

(21) Appl. No.: 18/990,295

(22) Filed: Dec. 20, 2024

Related U.S. Application Data
(63) Continuation-in-part of application No. PCT/KR2023/013537, filed on Sep. 8, 2023.

(30) Foreign Application Priority Data
Sep. 23, 2022 (KR) 10-2022-0120916
Aug. 4, 2023 (KR) 10-2023-0102473

(51) Int. Cl. G01R 31/392; G01R 19/165; G01R 31/367; G01R 31/3835; G01R 31/396

(52) U.S. Cl. CPC G01R 31/392; G01R 19/16542; G01R 31/367; G01R 31/3835; G01R 31/396

(57) ABSTRACT

According to aspects of the disclosure, a battery diagnosis apparatus includes: a sensor configured to generate first open circuit voltage (OCV) data by measuring an OCV from a diagnosis target battery; and a controller configured to: obtain first SOC data regarding a state of charge (SOC) of the diagnosis target battery based on the first OCV data, derive second SOC data for estimating the SOC of the diagnosis target battery based on the first SOC data, obtain second OCV data of the diagnosis target battery based on the second SOC data, and diagnose a state of the diagnose target battery based on the first OCV data and the second OCV data.

### CROSS-REFERENCE TO RELATED APPLICATIONS

This application is a continuation-in-part of International Application No. PCT/KR2023/013537 filed on Sep. 8, 2023, which claims priority from Korean Patent Application No. 10-2022-0120916 filed on Sep. 23, 2022 and Korean Patent Application No. 10-2023-0102473 filed on Aug. 4, 2023, all of which are incorporated herein by reference.

### BACKGROUND

Secondary batteries are chargeable/dischargeable batteries and may include nickel (Ni)/cadmium (Cd) batteries, Ni/metal hydride (MH) batteries, etc., and lithium-ion batteries. Among secondary batteries, lithium-ion batteries may have a higher energy density than Ni/Cd batteries, Ni/MH batteries, etc. Lithium-ion batteries may also be manufactured to be small and lightweight. Lithium-ion batteries may be applied as power sources for mobile devices, energy storage systems, or electric vehicles, as examples.

Diagnosis of abnormal behavior of the lithium-ion batteries may be performed based on battery voltage to inspect the manufacturing quality and determine whether a defect has occurred. For example, abnormal behavior of the battery voltage may be diagnosed conventionally by analyzing deviations in cell voltages across multiple battery cells. However, this diagnosis method may have limited accuracy for detecting subtle voltage abnormalities.

### Technical Problem and Solution

Conventional methods for diagnosing battery abnormalities may have limitations in detecting subtle voltage behavior issues, especially when there is little apparent change in overall battery voltage. Therefore, the battery diagnosis approach described herein may determine whether there is an abnormality in voltage behavior, even when there is little change in the battery voltage, based on analyzing changes in differences between measured open circuit voltage data and estimated open circuit voltage data over periods of time, thus enabling more accurate and earlier detection of battery abnormalities compared to the conventional methods.

By monitoring battery health using this approach, the lifespan and reliability of battery systems may be improved. For example, electric vehicles utilizing this approach could have increased range and reduced maintenance costs for consumers. This approach may also enable earlier detection of abnormal battery cells in these electric vehicles, allowing for timely repair or replacement of problematic cells before they cause more significant issues. This proactive maintenance capability could help extend overall battery pack life and reduce vehicle performance degradation over time.

The battery diagnosis approach may also have applications in manufacturing quality control. By applying this approach during production testing, manufacturers may be able to identify and screen out defective battery cells with subtle abnormalities that might otherwise go undetected using the conventional methods. This could lead to improved overall quality and performance of battery products reaching end users.

The battery diagnosis approach described herein may provide several improvements and practical applications in battery management and diagnostics. In some aspects, the approach may enable more accurate and earlier detection of battery abnormalities compared to the conventional methods, which may allow for proactive maintenance and replacement of faulty battery cells before they cause system-wide issues.

### BRIEF SUMMARY

Aspects of the disclosure provide a battery diagnosis approach to determine whether there is an abnormality in voltage behavior, even when there is little change in the battery voltage. The diagnosis approach is based on changes in differences between measured open circuit voltage data and estimated open circuit voltage data over periods of time.

According to aspects of the disclosure, a battery diagnosis apparatus includes: a sensor configured to generate first open circuit voltage (OCV) data based on measuring OCV values from a battery; and a controller configured to: obtain first state of charge (SOC) data regarding a SOC of the battery based on the first OCV data; derive second SOC data for estimating the SOC of the battery based on the first SOC data; obtain second OCV data of the battery based on the second SOC data; and diagnose a state of the battery based on the first OCV data and the second OCV data.

In some examples, the battery includes a plurality of battery cells; the first OCV data includes a plurality of OCV values measured at a plurality of time points for each of the plurality of battery cells; and the first SOC data includes a plurality of SOC values converted from the plurality of OCV values.

In some examples, the controller is further configured to: calculate, for each battery cell, an average SOC value over the plurality of time points; calculate, for each battery cell, a relative capacity value based on the average SOC values for each battery cell; and calculate, for each battery, a plurality of estimated SOC values at the plurality of time points based on the relative capacity values, the second SOC data including the plurality of estimated SOC values. In some examples, the controller is further configured to: calculate a pseudoinverse matrix of an average SOC matrix indicating the average SOC value for each battery cell; and calculate a relative capacity matrix indicating the relative capacity value for each battery cell by multiplying the pseudoinverse matrix by an SOC matrix indicating the plurality of SOC values. In some examples, the controller is further configured to calculate an estimated SOC matrix indicating the plurality of estimated SOC values by multiplying the average SOC matrix by the relative capacity matrix.

In some examples, the controller is further configured to: derive OCV deviation data based on a difference between the first OCV data and the second OCV data; and diagnose the state of the battery based on the OCV deviation data. In some examples, the battery includes a plurality of battery cells; the first OCV data comprises a plurality of OCV values measured at a plurality of time points for each of the plurality of battery cells; the second OCV data comprises a plurality of estimated OCV values converted from a plurality of estimated SOC values at the plurality of time points for each of the plurality of battery cells; and the OCV deviation data comprises a plurality of OCV deviation values at the plurality of time points for each of the plurality of battery. In some examples, the controller is further configured to: calculate, for each battery cell, a plurality of OCV deviation change amounts indicating a difference between an OCV deviation value at a current time point and an OCV deviation value at a previous time point; and diagnose a state of each battery cell based on the plurality of OCV deviation change amounts for each battery cell. In some examples, the controller is further configured to diagnose that an abnormality occurs in a battery cell among the plurality of battery cells based on the plurality of OCV deviation change amounts for that battery cell being greater than an upper limit of a predetermined range or less than a lower limit of the predetermined range.

In some examples, the controller is further configured to: convert the first OCV data into the first SOC data based on an OCV-SOC mapping table; and convert the second SOC data into the second OCV data based on the OCV-SOC mapping table.

According to aspects of the disclosure, a battery diagnosis method includes: generating first open circuit voltage (OCV) data based on measuring OCV values from a battery; obtaining first state of charge (SOC) data regarding a SOC of the battery based on the first OCV data; deriving second SOC data for estimating the SOC of the battery based on the first SOC data; obtaining second OCV data of the battery based on the second SOC data; and diagnosing a state of the battery based on the first OCV data and the second OCV data.

In some examples, the battery includes a plurality of battery cells; the first OCV data includes a plurality of OCV values measured at a plurality of time points for each of the plurality of battery cells; and the first SOC data includes a plurality of SOC values converted from the plurality of OCV values. In some examples, the method further includes: calculating, for each battery cell, an average SOC value over the plurality of time points; calculating, for each battery cell, a relative capacity value based on the average SOC values for each battery cell; and calculating, for each battery, a plurality of estimated SOC values at the plurality of time points based on the relative capacity values, the second SOC data including the plurality of estimated SOC values. In some examples, the method further includes: calculating a pseudoinverse matrix of an average SOC matrix indicating the average SOC value for each battery cell; and calculating a relative capacity matrix indicating the relative capacity value for each battery cell by multiplying the pseudoinverse matrix by an SOC matrix indicating the plurality of SOC values. In some examples, the method further includes calculating an estimated SOC matrix indicating the plurality of estimated SOC values by multiplying the average SOC matrix by the relative capacity matrix.

In some examples, the method further includes: deriving OCV deviation data based on a difference between the first OCV data and the second OCV data; and diagnosing the state of the battery based on the OCV deviation data. In some examples, the battery includes a plurality of battery cells; the first OCV data includes a plurality of OCV values measured at a plurality of time points for each of the plurality of battery cells; the second OCV data includes a plurality of estimated OCV values converted from a plurality of estimated SOC values at the plurality of time points for each of the plurality of battery cells; and the OCV deviation data includes a plurality of OCV deviation values at the plurality of time points for each of the plurality of battery. In some examples, the method further includes: calculating, for each battery cell, a plurality of OCV deviation change amounts indicating a difference between an OCV deviation value at a current time point and an OCV deviation value at a previous time point; and diagnosing a state of each battery cell based on the plurality of OCV deviation change amounts for each battery cell. In some examples, the method further includes diagnosing that an abnormality occurs in a battery cell among the plurality of battery cells based on the plurality of OCV deviation change amounts for that battery cell being greater than an upper limit of a predetermined range or less than a lower limit of the predetermined range.

According to aspects of the disclosure, a non-transitory computer readable medium storing instructions that, when executed by one or more processors, cause the one or more processors to perform a battery diagnosis method, the method including: generating first open circuit voltage (OCV) data based on measuring OCV values from a battery; obtaining first state of charge (SOC) data regarding a SOC of the battery based on the first OCV data; deriving second SOC data for estimating the SOC of the battery based on the first SOC data; obtaining second OCV data of the battery based on the second SOC data; and diagnosing a state of the battery based on the first OCV data and the second OCV data.

### BRIEF DESCRIPTION OF DRAWINGS

FIG. 1 illustrates components of a battery diagnosis system according to aspects of the disclosure.

FIG. 2 illustrates components of a battery diagnosis apparatus according to aspects of the disclosure.

FIG. 3 illustrates an operating process of a battery diagnosis apparatus according to aspects of the disclosure.

FIG. 4 illustrates a process of measuring an open circuit voltage (OCV) from a diagnosis target battery according to aspects of the disclosure.

FIG. 5 illustrates a process of generating actually measured OCV data according to aspects of the disclosure.

FIG. 6 illustrates a process of converting actually measured OCV data into estimated SOC data according to aspects of the disclosure.

FIG. 7 illustrates a process of calculating a relative capacity value of each battery cell based on an average state of charge (SOC) value according to aspects of the disclosure.

FIG. 8 illustrates a process of calculating a plurality of estimated OCV values based on a relative capacity value according to aspects of the disclosure.

FIG. 9 illustrates a process of generating estimated SOC data and estimated OCV data according to aspects of the disclosure.

FIG. 10 illustrates a process of converting estimated SOC data into estimated OCV data according to aspects of the disclosure.

FIG. 11 illustrates a process of deriving OCV deviation data based on a difference between actually measured OCV data and estimated OCV data according to aspects of the disclosure.

FIG. 12 illustrates a process of calculating a plurality of OCV deviation change amounts based on OCV deviation data according to aspects of the disclosure.

FIG. 13 illustrates a process of diagnosing a state of each battery cell based on a plurality of OCV deviation change amounts according to aspects of the disclosure.

FIG. 14 illustrates operations of a battery diagnosis method according to aspects of the disclosure.

### DETAILED DESCRIPTION

Aspects of the disclosure are described with reference to the accompanying drawings. However, the description is not intended to limit the disclosure to particular examples, and the disclosure should be construed as including various modifications, equivalents, and/or alternatives according to the examples described herein.

It should be appreciated that aspects of the disclosure and the terms used therein are not intended to limit the technological features set forth herein to a particular example and include various changes, equivalents, or replacements for a corresponding example. With regard to the description of the drawings, similar reference numerals may be used to refer to similar or related elements. It is to be understood that a singular form of a noun corresponding to an item may include one or more of the items, unless the relevant context clearly indicates otherwise.

Terms such as “include”, “constitute” or “have” described above may mean that the corresponding component may be inherent unless otherwise stated, and thus should be construed as further including other components rather than excluding other components.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}”, “2^{nd},” “first”, “second”, “A”, “B”, “(a)”, or “(b)” may be used to simply distinguish a corresponding component from another, and does not limit the components in other aspect (e.g., importance or order), unless mentioned otherwise.

As used herein, when an element (e.g., a first element) is referred to, with or without the term “operatively” or “communicatively”, as “connected with”, “coupled with”, or “linked with”, or “coupled to” or “connected to” to another element (e.g., a second element), it means that the element may be connected with the other element directly (e.g., wiredly or wirelessly), or indirectly (e.g., via a third element).

A method according to aspects of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices directly. If distributed online, at least part of the computer program product may be temporarily generated or at least temporarily stored in the machine-readable storage medium, such as memory of the manufacturer's server, a server of the application store, or a relay server.

According to aspects of the disclosure, each component (e.g., a module or a program) of the above-described components may include a single entity or multiple entities, and some of the multiple entities may be separately disposed in different components. According to aspects of the disclosure, one or more of the above-described components may be omitted, or one or more other components may be added. Alternatively or additionally, a plurality of components (e.g., modules or programs) may be integrated into a single component. In such a case, according to aspects of the disclosure, the integrated component may still perform one or more functions of each of the plurality of components in the same or similar manner as they are performed by a corresponding one of the plurality of components before the integration. According to aspects of the disclosure, operations performed by the module, the program, or another component may be carried out sequentially, in parallel, repeatedly, or heuristically, or one or more of the operations may be executed in a different order or omitted, or one or more other operations may be added.

The technology generally relates to diagnosing abnormalities in voltage behavior of batteries based on changes in differences between measured open circuit voltage data and estimated open circuit voltage data over periods of time.

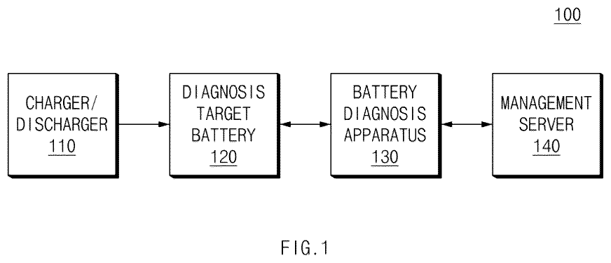

FIG. 1 illustrates components of a battery diagnosis system according to aspects of the disclosure. Referring to FIG. 1, a battery diagnosis system 100 may include a charger/discharger 110, a diagnosis target battery 120, a battery diagnosis apparatus 130, and a management server 140. However, without being limited thereto, some components may be omitted from the battery diagnosis system 100 or other general-purpose components may be further included in the battery diagnosis system 100.

The battery diagnosis system 100 identifies a state of the diagnosis target battery 120. The charger/discharger 110 applies a test voltage to the diagnosis target battery 120, and the battery diagnosis apparatus 130 measures response data output by the diagnosis target battery 120 in response to the test voltage.

The charger/discharger 110 may be configured to charge and/or discharge the diagnosis target battery 120. The charger/discharger 110 applies the test voltage to the diagnosis target battery 120. The test voltage may include a plurality of charge/discharge cycle voltages. To this end, the charger/discharger 110 may include a power supply device for applying various types of voltage and/or current to the diagnosis target battery 120. In some examples, the charger/discharger 110 may be included in the battery diagnosis apparatus 130 instead of being provided separately from the battery diagnosis apparatus 130.

The diagnosis target battery 120 refers to a diagnosis target of the battery diagnosis system 100. The diagnosis target battery 120 may include a plurality of battery cells. For example, the diagnosis target battery 120 may include m battery cells, for each of which voltage measurement may be performed n times, such that m*n voltage measurement values may be generated. In some examples, the diagnosis target battery 120 may include a plurality of battery modules, where each of the plurality of battery modules includes a plurality of battery cells, or the diagnosis target battery 120 may include a battery pack, wherein the battery pack includes a plurality of battery cells.

The battery diagnosis apparatus 130 performs operations for determining whether the diagnosis target battery 120 is abnormal. The battery diagnosis apparatus 130 performs voltage measurement and data processing to diagnose which cell of the diagnosis target battery 120 has an abnormal voltage behavior.

The management server 140 manages the state of the diagnosis target battery 120. The management server 140 may be connected to the battery diagnosis apparatus 130 through wired and/or wireless data communication. The battery diagnosis apparatus 130 provides data, e.g., state, abnormality, and/or diagnosis result, of the diagnosis target battery 120 to the management server 140. The management server 140 may record the data and/or output the data to a user device. The management server 140 may control the battery diagnosis apparatus 130 to identify the state of the diagnosis target battery 120 at the request of a system manager or a battery user.

In some examples, the management server 140 may perform at least some of operations for determining whether the diagnosis target battery 120 is abnormal on behalf of the battery diagnosis apparatus 130. The management server 140 may receive data for diagnosing the diagnosis target battery 120 from the battery diagnosis apparatus 130, perform diagnosis procedures, and transmit a result to the battery diagnosis apparatus 130. In some examples, the management server 140 may install energy management software necessary for diagnosing the diagnosis target battery 120 on the battery diagnosis apparatus 130 and provide update information of the energy management software to the battery diagnosis apparatus 130.

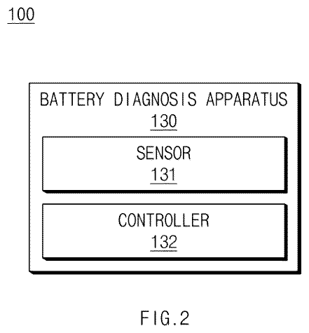

FIG. 2 illustrates components of a battery diagnosis apparatus according to aspects of the disclosure. The battery diagnosis apparatus 130 includes a sensor 131 and a controller 132. However, without being limited thereto, some components may be omitted from the battery diagnosis apparatus 130 or other general-purpose components may be further included in the battery diagnosis apparatus 130.

The sensor 131 and the controller 132 may be electrically connected to each other through communication between devices such as a bus, general purpose input and output (GPIO), serial peripheral interface (SPI), mobile industry processor interface (MIPI), etc.

The sensor 131 is configured to measure the voltage from the diagnosis target battery 120. For example, the sensor 131 may measure an output voltage generated by the diagnosis target battery 120 in response to a test cycle voltage applied to the diagnosis target battery 120 by the charger/discharger 110. To this end, the sensor 131 may include measuring means such as a voltmeter, an ammeter, and/or a thermometer, as examples.

The controller 132 is configured to execute instructions that implement operations of the battery diagnosis apparatus 130. The controller 132 may be implemented with an array of multiple logic gates or a general-purpose microprocessor for processing the operations. The controller may include a single processor or a plurality of processors. For example, the controller 132 may be implemented as a central processing unit (CPU), a graphic processing unit (GPU), and/or an application processor (AP).

The instructions may be stored in a memory (not shown). The controller 132 may process the operations by executing the instructions stored in the memory. The controller 132 may be configured separately from or integrally with the memory. The memory may store various data, instructions, mobile applications, computer programs, etc. For example, the memory may be implemented in the form of non-volatile memory such as ROM, PROM, EPROM, EEPROM, flash memory, PRAM, MRAM, FRAM, etc., or volatile memory such as DRAM, SRAM, SDRAM, RRAM, HDD, SSD, SD, Micro-SD, etc., or may be implemented in the form of a combination thereof. The memory may be a transitory or non-transitory computer-readable medium.

The sensor 131 may be configured to measure OCV from the diagnosis target battery 120 and generate first OCV data. The first OCV data may refer to measured OCV values. For example, OCV values may be measured n times for each of the m battery cells of the diagnosis target battery 120, where the first OCV data includes m*n OCV values. The sensor 131 may measure the voltage from the diagnosis target battery 120 and derive the OCVs of the diagnosis target battery 120 based on the measured voltage.

The controller 132 may be configured to obtain first SOC data regarding the SOC of the diagnosis target battery 120 based on the first OCV data. For example, m*n OCV values of the first OCV data may be converted into m*n SOC values, where the first SOC data includes m*n SOC values. The controller 132 may convert the first OCV data into first SOC data using an OCV-SOC mapping table.

The controller 132 of the battery diagnosis apparatus 130 may be configured to derive second SOC data for estimating the SOC of the diagnosis target battery 120 based on the first SOC data. The first SOC data may refer to SOC values converted from the first OCV data, and the second SOC data may refer to values obtained by estimating the SOC of the diagnosis target battery 120. The second SOC data may be estimated based on an average SOC value and a relative capacity value of each battery cell of the diagnosis target battery 120.

The controller 132 of the battery diagnosis apparatus 130 may be configured to obtain second OCV data of the diagnosis target battery 120 based on the second SOC data. For example, the second SOC data may include m*n estimated SOC values that may be converted into m*n estimated OCV values, where the second OCV data includes m*n estimated OCV values. The controller 132 may convert the second SOC data into the second OCV data using an OCV-SOC mapping table. The OCV-SOC mapping table may be the same table as for converting the first OCV data into first SOC data, or may be a different table.

The controller 132 is configured to diagnose the state of the diagnosis target battery 120 based on the first OCV data and the second OCV data. The controller 132 may diagnose the state of the diagnosis target battery 120 based on a deviation between the first OCV data and the second OCV data.

The controller 132 may derive OCV deviation data based on the difference between the first OCV data and the second OCV data. For example, the first OCV data OCVs may include m*n measured OCV values, the second OCV data may contain m*n estimated OCV values, and a difference between the measured OCV values and estimated OCV values may produce m*n OCV deviation values, where the OCV deviation data includes m*n OCV deviation values.

The controller 132 may diagnose the state of the diagnosis target battery 120 based on the OCV deviation data. The controller 132 may diagnose whether abnormality occurs in a voltage behavior of each battery cell of the diagnosis target battery 120 by comparing the OCV deviation data with a threshold, allowing for voltage behavior abnormality to be detected even when there is no sudden voltage change due to cell disconnection, short circuit, etc.

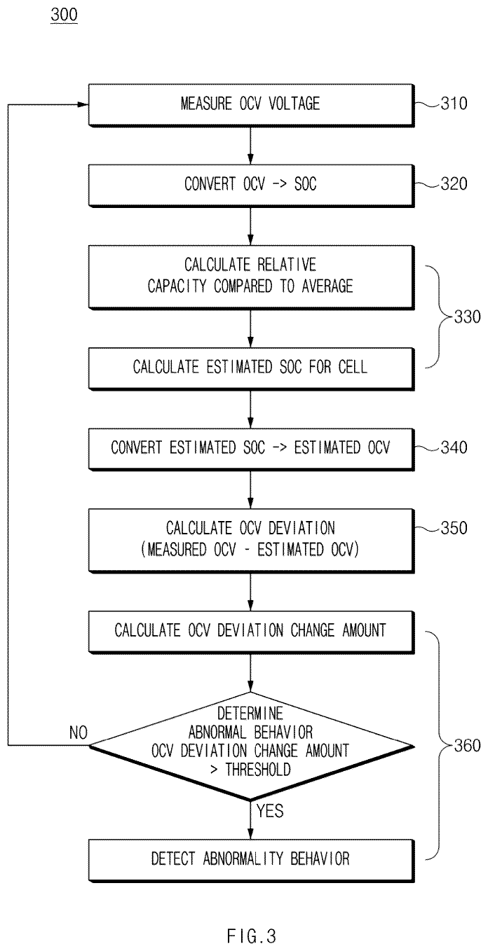

FIG. 3 illustrates an operating process of a battery diagnosis apparatus according to aspects of the disclosure. The operating process 300 of the battery diagnosis apparatus 130 may include a first process 310 to a sixth process 360.

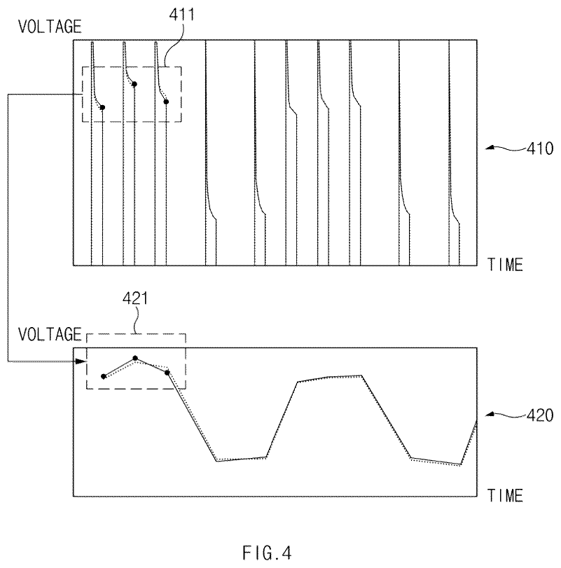

In the first process 310, the battery diagnosis apparatus 130 measures an OCV voltages of the diagnosis target battery 120 and generates first OCV data from the measured OCV voltages. FIG. 4 illustrates a process of measuring OCVs from a diagnosis target battery using a charge/discharge profile 410 and an OCV graph 420 according to aspects of the disclosure. The charge/discharge profile 410 may indicate a voltage measured from any one battery cell of the diagnosis target battery 120 when a charge/discharge cycle voltage is applied to the battery cell. Peak values 411 in a measurement cycle of the charge/discharge profile 410 may be measured OCV values 421. For example, for one battery cell, the OCV graph 420 may include n measured OCV values 421.

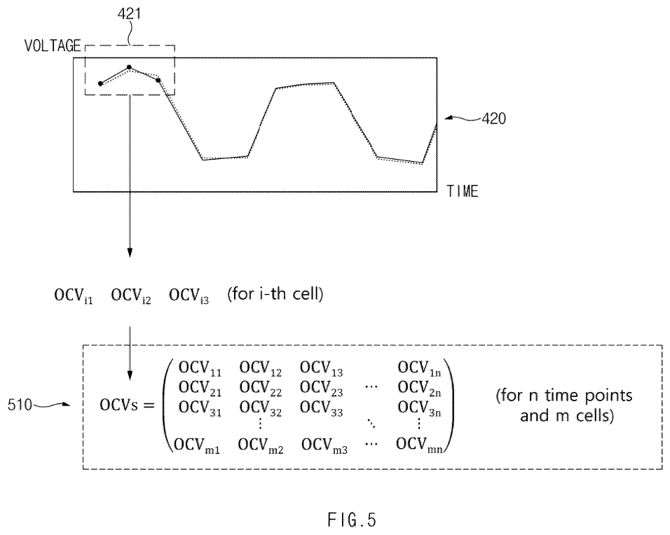

FIG. 5 illustrates a process of generating first OCV data 510 using the OCV graph 420 according to aspects of the disclosure. The diagnosis target battery 120 may include a plurality of battery cells, where the first OCV data 510 may include a plurality of OCV values measured at a plurality of time points for each battery cell of the plurality of battery cells. For example, the OCV graph 420 may include n actually measured OCV values 421 for an i^{th} battery cell, and the first OCV data 510 for m battery cells of the diagnosis target battery 120 may be m*n actually measured OCV values. The first OCV data 510 may be expressed in the form of a matrix with a size of m*n.

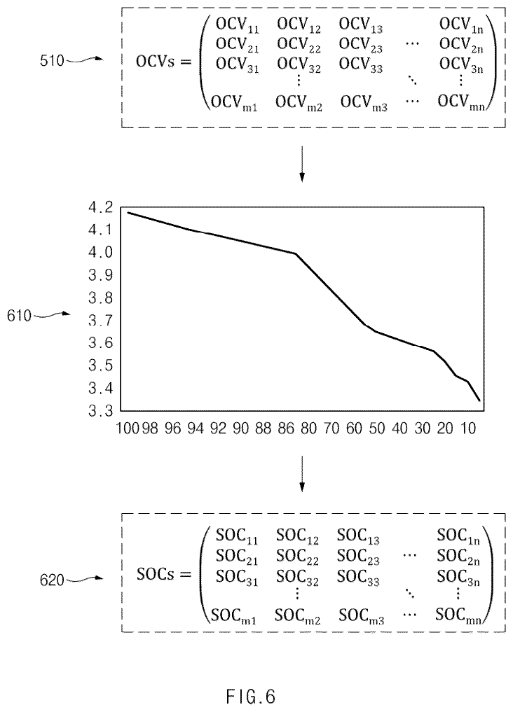

Referring back to FIG. 3, in the second process 320, the battery diagnosis apparatus 130 converts the first OCV data into first SOC data. FIG. 6 illustrates a process of converting the first OCV data 510 into first SOC data 620 using an OCV-SOC mapping table 610 according to aspects of the disclosure. The OCV-SOC mapping table 610 may refer a table which maps an OCV value of a vertical axis or horizontal axis to an SOC value of a horizontal axis or vertical axis and records a mapping relationship therebetween.

Referring back to FIG. 3, in the third process 330, the battery diagnosis apparatus 130 calculates an average SOC value of the first SOC data and relative capacity values of the first SOC data based on the average SOC value. The battery diagnosis apparatus calculates estimated SOC data based on the relative capacity value compared to an average SOC value.

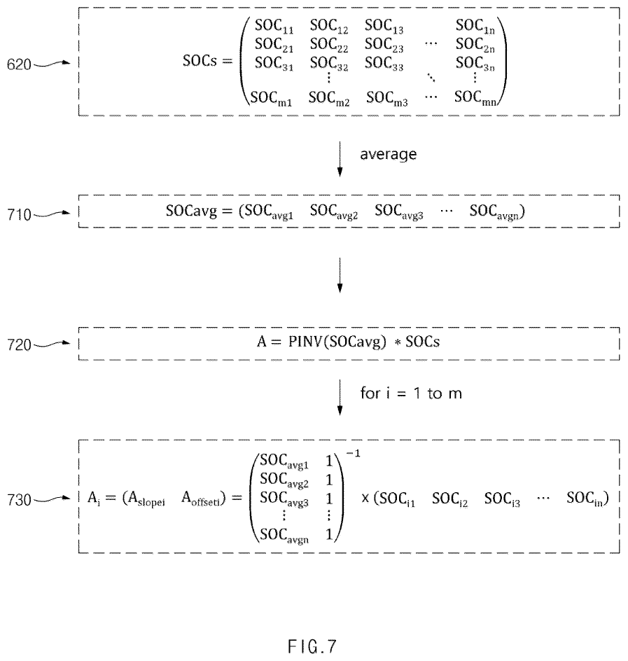

FIG. 7 illustrates a process of calculating a relative capacity values 720, 730 of each battery cell based on an average SOC value 710 from first SOC data 620 according to aspects of the disclosure. The average SOC value 710 may be calculated from an average of the first SOC data 620 for each of a plurality of time points 1, . . . , n. The relative capacity value 720 may be calculated based on the average SOC value 710 and the first SOC data 620 using a pseudoinverse matrix (PINV) operation of the average SOC value 710. The pseudoinverse matrix may refer to a Moore-Penrose inverse matrix, as an example. For example, the relative capacity value 730 of an i^{th} battery cell from the first battery cell to the m^{th} battery cell may be calculated. The relative capacity value 730 of the i^{th} battery cell may include a slope component Aₛₗₒₚₑᵢ and an offset component A_{offseti}.

For example, the PINV matrix of the

$$( PINV ( SOCavg ) = {( \begin{matrix}{SOC}_{avg 1} & 1 \\ {SOC}_{avg 2} & 1 \\ {SOC}_{avg 3} & 1 \\ ⋮ & ⋮ \\ {SOC}_{avgn} & 1\end{matrix} )}^{- 1} )$$

average SOC matrix

$$( \begin{matrix}{SOC}_{avg 1} & 1 \\ {SOC}_{avg 2} & 1 \\ {SOC}_{avg 3} & 1 \\ ⋮ & ⋮ \\ {SOC}_{avgn} & 1\end{matrix} )$$

representing the average SOC value 710 of each battery cell may be calculated. The relative capacity matrix A representing the relative capacity value Aᵢ may be calculated by by multiplying the SOC matrix (SOCᵢ₁ SOCᵢ₂ SOCᵢ₃ . . . SOCᵢₙ) representing the plurality of SOC values SOCs for each battery cell by the pseudoinverse matrix (PINV (SOCavg)).

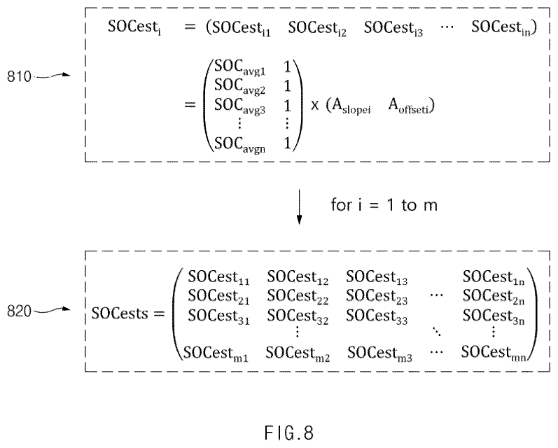

FIG. 8 illustrates a process of calculating second SOC data 820 from a plurality of estimated SOC values 810 of an i^{th} battery cell based on the relative capacity value 730 and the average SOC value 710 according to aspects of the disclosure. The plurality of estimated SOC values 810 of the i^{th} battery cell may be calculated based on the slope component Aₛₗₒₚₑᵢ, the offset component A_{offseti}, and the average SOC value 710. By calculating the plurality of estimated SOC values 810 of the i^{th} battery cell from the first battery cell to the m^{th} battery cell, the second SOC data 820 of the diagnosis target battery 120 may be calculated. For example, the average SOC matrix

$$( \begin{matrix}{SOC}_{avg 1} & 1 \\ {SOC}_{avg 2} & 1 \\ {SOC}_{avg 3} & 1 \\ ⋮ & ⋮ \\ {SOC}_{avgn} & 1\end{matrix} )$$

representing the average SOC values of the battery cells may be multiplied by the relative capacity matrix A to calculate the estimated SOC matrix indicating the plurality of estimated SOC values 810 of each battery cell.

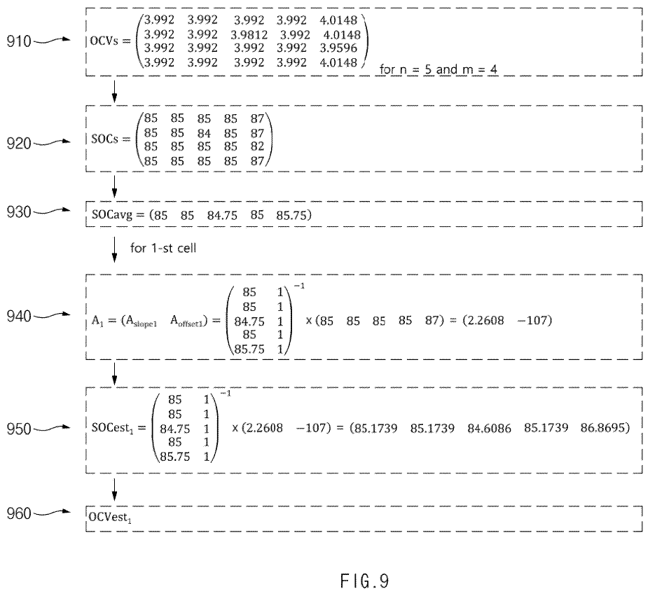

FIG. 9 illustrates an example process of generating second SOC data and second OCV data according to aspects of the disclosure. Here, a process of converting first OCV data OCVs 910 measured for four battery cells into second OSC data and second OCV data at five time points (n=5) is shown.

The first OCV data 910 may be converted into the first SOC data 920 based on the OCV-SOC mapping table 610. An average SOC value 930 may be calculated based on the first SOC data SOCs 920.

A relative capacity value 940 for the first battery cell may be calculated by multiplying a pseudoinverse matrix

$${( \begin{matrix}85 & 1 \\ 85 & 1 \\ 84.75 & 1 \\ 85 & 1 \\ 85.75 & 1\end{matrix} )}^{- 1}$$

of an average SOC matrix

$$( \begin{matrix}85 & 1 \\ 85 & 1 \\ 84.75 & 1 \\ 85 & 1 \\ 85.75 & 1\end{matrix} )$$

by the average SOC value 930, for the first battery cell (i=1) among four battery cells based on the average SOC value 930. Thereafter, by multiplying the pseudoinverse matrix

$${( \begin{matrix}85 & 1 \\ 85 & 1 \\ 84.75 & 1 \\ 85 & 1 \\ 85.75 & 1\end{matrix} )}^{- 1}$$

of the average SOC matrix

$$( \begin{matrix}85 & 1 \\ 85 & 1 \\ 84.75 & 1 \\ 85 & 1 \\ 85.75 & 1\end{matrix} )$$

by the relative capacity value 940, estimated SOC values 950 for the first battery cell may be calculated, and the OCV-SOC mapping table 610 may be applied thereto to calculate estimated OCV values 960 for the first battery cell.

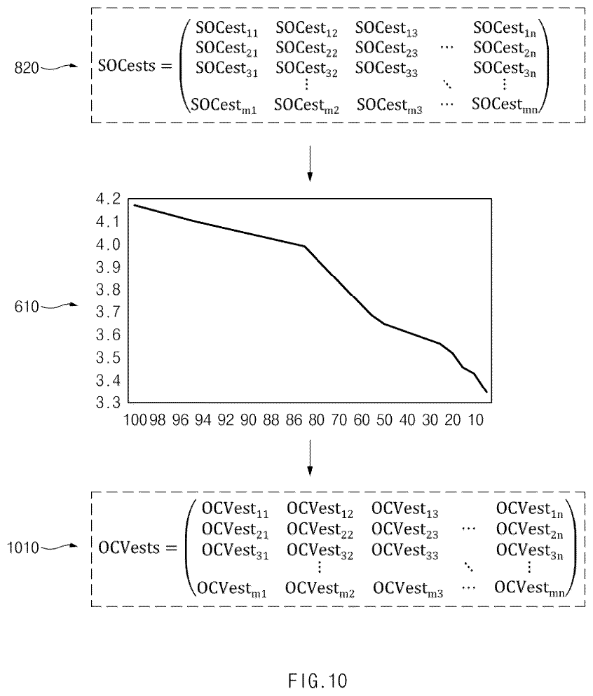

Referring back to FIG. 3, in the fourth process 340, the battery diagnosis apparatus 130 converts the estimated SOC data into estimated OCV data. FIG. 10 illustrates a process of converting second SOC data 820 into second OCV data 1010 using the OCV-SOC mapping table 610 according to aspects of the disclosure. The OCV-SOC mapping table 610 may be the same table used for converting the first OCV data 510 into the first SOC data 620.

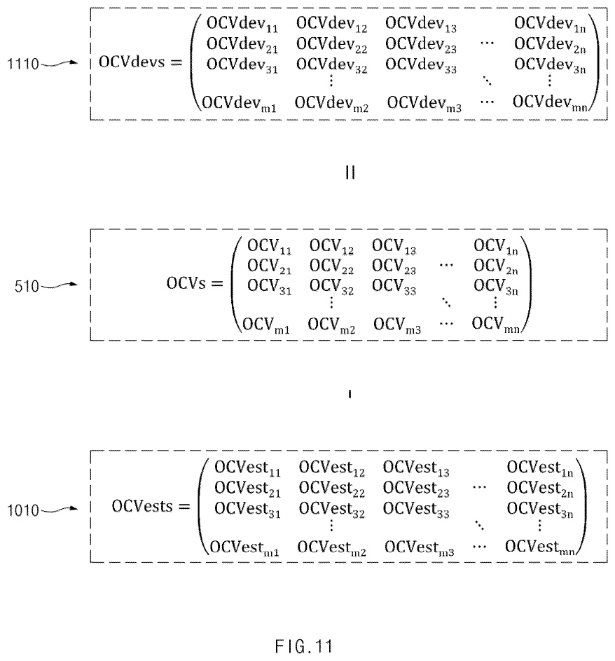

Referring back to FIG. 3, in the fifth process 350, the battery diagnosis apparatus 130 calculates OCV deviation data based on the first OCV data and the second OCV data. FIG. 11 illustrates a process of deriving OCV deviation data 1110 based on a difference between the first OCV data 510 and the second OCV data 1010 according to aspects of the disclosure. For example, the OCV deviation data 1110 may include a plurality of OCV deviation values OCVdevᵢ₁, OCVdevᵢ₂, . . . , OCVdevᵢₙ of each battery cell at a plurality of time points 1 to n.

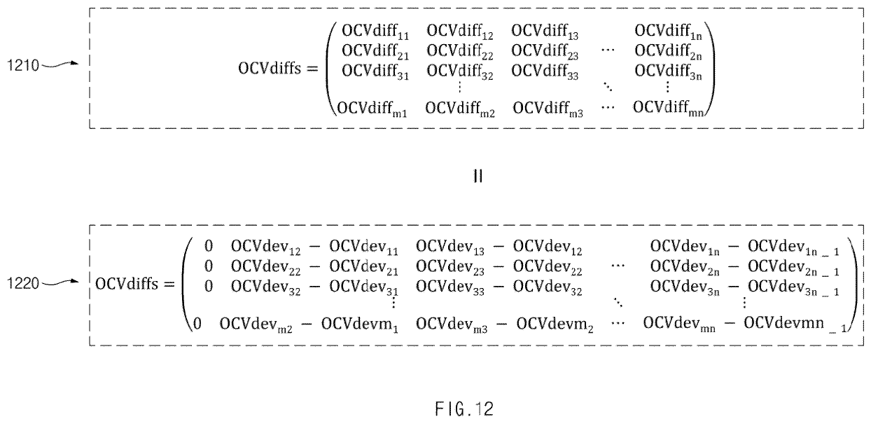

Referring back to FIG. 3, in the sixth process 360, the battery diagnosis apparatus 130 calculates an OCV deviation change amount based on the OCV deviation data. The battery diagnosis apparatus 130 compares the OCV deviation change amount with a threshold value to detect whether there is a voltage behavior abnormality of each cell of the target diagnosis battery 120. FIG. 12 illustrates a process of calculating a plurality of OCV deviation change amounts 1210, 1220 based on a difference between a value at a current time point and a value at a previous time point of the OCV deviation data 1110 according to aspects of the disclosure. A plurality of OCV deviation change amounts 1210 indicating a difference 1220 between an OCV deviation value at a current time point and an OCV deviation value at a previous time point are calculated based on the plurality of OCV deviation values of each battery cell. A state of each battery cell is diagnosed based on the plurality of OCV deviation change amounts 1210 of each battery cell by comparing the OCV change amounts 1210 to a predetermined threshold range and threshold value.

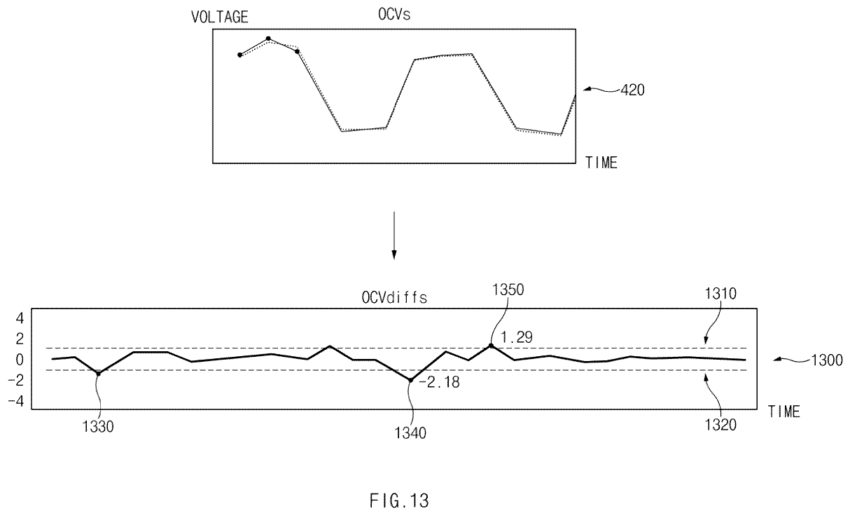

FIG. 13 illustrates a process of diagnosing a state of each battery cell based on a plurality of OCV deviation change amounts according to aspects of the disclosure. In a diagnosis process of the diagnosis target battery 120, upon input of the first OCV data 420, OCV deviation change amounts 1300 including the plurality of OCV deviation change amounts 1210 of each battery cell may be derived, and voltage behavior abnormality of each battery cell of the diagnosis target battery 120 may be detected based on the OCV deviation change amount 1300.

In the OCV deviation change amount 1300, an upper limit 1310 and a lower limit 1320 in a normal range may be set. When an OCV deviation change amount of a specific battery cell exceeds the upper limit 1310 or falls short of the lower limit 1320 at a specific time point, it may be diagnosed that voltage behavior abnormality occurs in the corresponding battery cell at excess/shortfall time points. For example, when the OCV deviation change amount falls out of a normal range at shortfall time points 1330 and 1340 and an excess time point 1350, a battery cell having the OCV deviation change amount 1300 may be diagnosed as an abnormal cell.

The upper limit 1310 and the lower limit 1320 of the normal range may be adjusted depending on battery performance requirements. When higher battery performance requirements are needed, the normal range may be narrowed, while when lower battery performance requirements are needed, the normal range may be widened. The abnormality of the battery cell may be diagnosed based on the number and/or frequency that the battery performance requirements fall out of the normal range. For example, the number and/or frequency that the battery performance requirements fall out of the normal range may be compared with a threshold value.

In response to a battery cell being diagnosed as abnormal, the battery diagnosis apparatus 130 may output a notification, such as to a user device, stop operation of the battery, and/or isolate the abnormal battery cell, such as via electrical and/or mechanical isolation. The battery diagnosis apparatus 130 or the management server 140 may initiate different actions depending on the severity of the abnormality based on, for example, the number and/or frequency that the battery performance requirements fall out of the normal range when compared to the threshold value or multiple threshold values. For minor abnormalities, e.g., a first threshold value, the battery diagnosis apparatus 130 or the management server 140 may flag the battery for more frequent monitoring. For moderate abnormalities, e.g., a second threshold value greater than the first threshold value, the battery diagnosis apparatus 130 or the management server 140 may recommend maintenance or replacement of specific battery cells. For severe abnormalities, e.g., a third threshold value greater than the second threshold value, the battery diagnosis apparatus 130 or the management server 140 may trigger an immediate shutdown of the battery system and alert operators. The battery diagnosis apparatus 130 or the management server 140 may also log detailed diagnostic data for later analysis in cases of abnormal diagnoses.

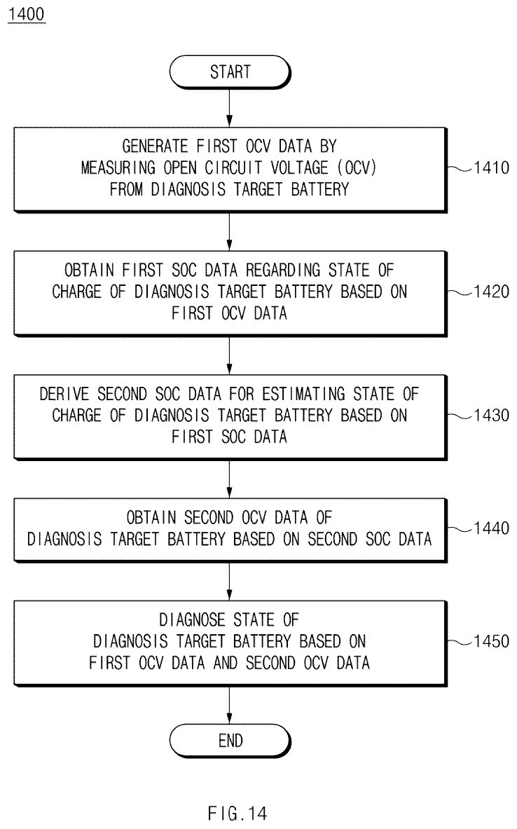

FIG. 14 illustrates operations of a battery diagnosis method according to aspects of the disclosure. The battery diagnosis method 1400 may include operations 1410 to 1460. However, without being limited thereto, some operations may be omitted and other general-purpose operations may be added, and operations of the battery diagnosis method 1400 may be executed in an order different from that shown.

The battery diagnosis method 1400 may include operations processed in time series by the battery diagnosis apparatus 130. Therefore, matters described for the battery diagnosis apparatus 130 above, even omitted below, may be equally applied to the battery diagnosis method 1400. Operations 1410 to 1460 of the battery diagnosis method 1400 may be performed by the sensor 131 and the controller 132 of the battery diagnosis apparatus 130.

In operation 1410, the battery diagnosis apparatus 130 may generate first OCV data by measuring an OCV from a diagnosis target battery.

In operation 1420, the battery diagnosis apparatus 130 may obtain first SOC data regarding an SOC of a diagnosis target battery based on the first OCV data.

In operation 1430, the battery diagnosis apparatus 130 may derive second SOC data for estimating the SOC of the diagnosis target battery based on the first SOC data.

In operation 1440, the battery diagnosis apparatus 130 may obtain second OCV data of the diagnosis target battery based on the second SOC data.

In operation 1450, the battery diagnosis apparatus 130 may diagnose the state of the diagnosis target battery based on the first OCV data and the second OCV data.

The battery diagnosis method 1400 may be implemented in the form of a computer program stored in a computer-readable storage medium. That is, the computer program may include instructions for implementing the battery diagnosis method 1400, and the instructions of the program may be stored in a computer-readable storage medium. The computer-readable storage medium may be transitory or non-transitory. The computer programs may include mobile applications.

For example, the computer-readable storage medium may include magnetic media such as hard disk, floppy disk, and magnetic tape, optical media such as compact disk read only memory (CD-ROM) and digital versatile disk (DVD), magneto-optical media such as floptical disk, and a hardware device especially configured to store and execute program instructions, such as read only memory (ROM), random access memory (RAM) and flash memory, etc. The computer program instructions may include a machine language code created by a complier and a high-level language code executable by a computer using an interpreter.

The above description is merely illustrative of the disclosure, and various modifications and variations will be possible without departing from the scope of the disclosure. Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

1. A battery diagnosis apparatus comprising:
a sensor configured to generate first open circuit voltage (OCV) data based on measuring OCV values from a battery; and
a controller configured to:
obtain first state of charge (SOC) data regarding a SOC of the battery based on the first OCV data;
derive second SOC data for estimating the SOC of the battery based on the first SOC data;
obtain second OCV data of the battery based on the second SOC data; and
diagnose a state of the battery based on the first OCV data and the second OCV data.

2. The battery diagnosis apparatus of claim 1, wherein:
the battery comprises a plurality of battery cells;
the first OCV data comprises a plurality of OCV values measured at a plurality of time points for each of the plurality of battery cells; and
the first SOC data comprises a plurality of SOC values converted from the plurality of OCV values.

3. The battery diagnosis apparatus of claim 2, wherein the controller is further configured to:
calculate, for each battery cell, an average SOC value over the plurality of time points;
calculate, for each battery cell, a relative capacity value based on the average SOC values for each battery cell; and
calculate, for each battery, a plurality of estimated SOC values at the plurality of time points based on the relative capacity values, the second SOC data comprising the plurality of estimated SOC values.

4. The battery diagnosis apparatus of claim 3, wherein the controller is further configured to:
calculate a pseudoinverse matrix of an average SOC matrix indicating the average SOC value for each battery cell; and
calculate a relative capacity matrix indicating the relative capacity value for each battery cell by multiplying the pseudoinverse matrix by an SOC matrix indicating the plurality of SOC values.

5. The battery diagnosis apparatus of claim 4, wherein the controller is further configured to calculate an estimated SOC matrix indicating the plurality of estimated SOC values by multiplying the average SOC matrix by the relative capacity matrix.

6. The battery diagnosis apparatus of claim 1, wherein the controller is further configured to:
derive OCV deviation data based on a difference between the first OCV data and the second OCV data; and
diagnose the state of the battery based on the OCV deviation data.

7. The battery diagnosis apparatus of claim 6, wherein:
the battery comprises a plurality of battery cells;
the first OCV data comprises a plurality of OCV values measured at a plurality of time points for each of the plurality of battery cells;
the second OCV data comprises a plurality of estimated OCV values converted from a plurality of estimated SOC values at the plurality of time points for each of the plurality of battery cells; and
the OCV deviation data comprises a plurality of OCV deviation values at the plurality of time points for each of the plurality of battery.

8. The battery diagnosis apparatus of claim 7, wherein the controller is further configured to:
calculate, for each battery cell, a plurality of OCV deviation change amounts indicating a difference between an OCV deviation value at a current time point and an OCV deviation value at a previous time point; and
diagnose a state of each battery cell based on the plurality of OCV deviation change amounts for each battery cell.

9. The battery diagnosis apparatus of claim 8, wherein the controller is further configured to diagnose that an abnormality occurs in a battery cell among the plurality of battery cells based on the plurality of OCV deviation change amounts for that battery cell being greater than an upper limit of a predetermined range or less than a lower limit of the predetermined range.

10. The battery diagnosis apparatus of claim 1, wherein the controller is further configured to:
convert the first OCV data into the first SOC data based on an OCV-SOC mapping table; and
convert the second SOC data into the second OCV data based on the OCV-SOC mapping table.

11. A battery diagnosis method comprising:
generating first open circuit voltage (OCV) data based on measuring OCV values from a battery;
obtaining first state of charge (SOC) data regarding a SOC of the battery based on the first OCV data;
deriving second SOC data for estimating the SOC of the battery based on the first SOC data;
obtaining second OCV data of the battery based on the second SOC data; and
diagnosing a state of the battery based on the first OCV data and the second OCV data.

12. The method of claim 11, wherein:
the battery comprises a plurality of battery cells;
the first OCV data comprises a plurality of OCV values measured at a plurality of time points for each of the plurality of battery cells; and
the first SOC data comprises a plurality of SOC values converted from the plurality of OCV values.

13. The method of claim 12, further comprising:
calculating, for each battery cell, an average SOC value over the plurality of time points;
calculating, for each battery cell, a relative capacity value based on the average SOC values for each battery cell; and
calculating, for each battery, a plurality of estimated SOC values at the plurality of time points based on the relative capacity values, the second SOC data comprising the plurality of estimated SOC values.

14. The method of claim 13, further comprising:
calculating a pseudoinverse matrix of an average SOC matrix indicating the average SOC value for each battery cell; and
calculating a relative capacity matrix indicating the relative capacity value for each battery cell by multiplying the pseudoinverse matrix by an SOC matrix indicating the plurality of SOC values.

15. The method of claim 14, further comprising calculating an estimated SOC matrix indicating the plurality of estimated SOC values by multiplying the average SOC matrix by the relative capacity matrix.

16. The method of claim 11, further comprising:
deriving OCV deviation data based on a difference between the first OCV data and the second OCV data; and
diagnosing the state of the battery based on the OCV deviation data.

17. The method of claim 16, wherein:
the battery comprises a plurality of battery cells;
the first OCV data comprises a plurality of OCV values measured at a plurality of time points for each of the plurality of battery cells;
the second OCV data comprises a plurality of estimated OCV values converted from a plurality of estimated SOC values at the plurality of time points for each of the plurality of battery cells; and
the OCV deviation data comprises a plurality of OCV deviation values at the plurality of time points for each of the plurality of battery.

18. The method of claim 17, further comprising:
calculating, for each battery cell, a plurality of OCV deviation change amounts indicating a difference between an OCV deviation value at a current time point and an OCV deviation value at a previous time point; and
diagnosing a state of each battery cell based on the plurality of OCV deviation change amounts for each battery cell.

19. The method of claim 18, further comprising diagnosing that an abnormality occurs in a battery cell among the plurality of battery cells based on the plurality of OCV deviation change amounts for that battery cell being greater than an upper limit of a predetermined range or less than a lower limit of the predetermined range.

20. A non-transitory computer readable medium storing instructions that, when executed by one or more processors, cause the one or more processors to perform a battery diagnosis method, the method comprising:
generating first open circuit voltage (OCV) data based on measuring OCV values from a battery;
obtaining first state of charge (SOC) data regarding a SOC of the battery based on the first OCV data;
deriving second SOC data for estimating the SOC of the battery based on the first SOC data;
obtaining second OCV data of the battery based on the second SOC data; and
diagnosing a state of the battery based on the first OCV data and the second OCV data.
